(19) United States
(12) Patent Application Publication
(10) Pub. No.: US 2026/0172007 A1
(43) Pub. Date: Jun. 18, 2026

(54) OSCILLATOR

(71) Applicant: Renesas Electronics Corporation, Tokyo (JP)

(72) Inventors: Hajime HAYASHIMOTO, Tokyo (JP); Shigeyuki YOKOSAWA, Tokyo (JP)

(73) Assignee: Renesas Electronics Corporation, Tokyo (JP)

(21) Appl. No.: 19/372,860

(22) Filed: Oct. 29, 2025

(30) Foreign Application Priority Data
Dec. 18, 2024 (JP) 2024-221807

(51) Int. Cl. H03K 3/03; H03K 17/687

(52) U.S. Cl. CPC H03K 3/0315; H03K 17/6871

(57) ABSTRACT

First and second reference current sources generate currents with opposing temperature characteristics and output a summed reference current. A ring oscillator outputs an output signal with an oscillation frequency corresponding to the reference current. The first reference current source has a first diode and first, second, and twelfth n-type transistors connected in series. A gate of the second n-type transistor is connected to a node, and a gate of the first n-type transistor is connected to a ground. The second reference current source has a third n-type transistor and a second diode in series, a fourth n-type transistor, a fifth p-type transistor, and a first resistor in series, and a sixth p-type transistor forming a current mirror with the fifth p-type transistor. Gates of the third and fourth n-type transistors are connected to an anode of the second diode. The second n-type transistor is connected to another node.

### CROSS-REFERENCE TO RELATED APPLICATIONS

This application claims priority under 35 U.S.C. § 119 to Japanese Patent Application No. 2024-221807 filed on Dec. 18, 2024. The disclosure of Japanese Patent Application No. 2024-221807, including the specification, drawings and abstract is incorporated herein by reference in its entirety.

### BACKGROUND

The present disclosure relates to an oscillator, and for example, relates to an oscillator which is used under a condition in which a surrounding environment changes.

In order to supply an operating clock to a circuit, an oscillator is widely used. Such an oscillator is required to output a signal having a fixed oscillation frequency without being affected by the environment of use.

There is disclosed a technique listed below.
[Patent Document 1] Japanese Unexamined Patent Application Publication No. 2004-48690

Patent Document 1 proposes an oscillator capable of preventing reduction in oscillation frequency at a time of temperature rise. The oscillator in Patent Document 1 has a oscillation frequency of 2.8 MHz at −40° C. and a oscillation frequency of 3.6 MHz at 150° C., when a power supply voltage is 1.8 V. In addition, the oscillator in Patent Document 1 has an oscillation frequency of 2.1 MHz at −40° C. and an oscillation frequency of 2.7 MHz at 150° C., when the power supply voltage is 2.5 V.

### SUMMARY

However, when the oscillator in Patent Document 1 is used for formation of a clock to be supplied to a flip-flop included in a digital circuit, variation of the oscillation frequency may be too large. The flip-flop is required to preferably secure a setup time and a hold time. The setup time is the minimum time for which data input of the flipflop should be stable before rising of a clock edge. The hold time is the minimum time for which data input of the flipflop should be stable after the rising of the clock edge.

When an oscillation frequency of the oscillator which generates a clock varies depending on temperature, a timing of rising and falling of the clock varies. Accordingly, a period of time to be used as the setup time and the hold time becomes short. Hence, a sufficient setup time and hold time cannot be secured. Thus, an oscillator which can suppress variation of the oscillation frequency with respect to temperature change is demanded.

Other objects and novel features will become apparent from the description of the present specification and the accompanied drawings.

According to one embodiment, an oscillator includes a first current source which generates a first current having a positive temperature characteristic according to a power supply voltage output from a power supply, a second current source which generates a second current having a negative temperature characteristic according to the power supply voltage, and outputs a reference current obtained by summing the first current and the second current, a ring oscillator which outputs an output signal with an oscillation frequency according to the reference current, and including a plurality of inverters in which transistors of a first conductivity type and transistors of a second conductivity type are complementarily connected. The first current source includes a first diode and a first transistor of the first conductivity type which are connected in series between the power supply and a ground in this order, and a second transistor of the first conductivity type and a second resistor which are connected in series between the second current source and the ground in this order. A control terminal of the second transistor is connected to a node between the first diode and the first transistor. A control terminal of the first transistor is connected to the ground. The second current source includes a third transistor of the first conductivity type and a second diode which are connected in series between the power supply and the ground in this order, a fifth transistor of the second conductivity type, a fourth transistor of the second conductivity type, and a first resistor which are connected in series between the power supply and the ground in this order, and a sixth transistor of the second conductivity type having one end connected between the power supply and the ring oscillator, and constituting a current mirror with the fifth transistor. A control terminal of each of the third and fourth transistors is connected to an anode of the second diode. The second transistor is connected between a node between the fourth transistor and the fifth transistor and the second resistor.

According to the one embodiment, it is possible to provide an oscillator capable of maintaining an oscillation frequency, regardless of temperature.

### BRIEF DESCRIPTION OF THE DRAWINGS

FIG. 1 is a graph showing a relation between a drain-source current and a gate-source voltage of a MOS transistor.

FIG. 2 is a circuit diagram showing a configuration of a typical ring oscillator.

FIG. 3 is a graph schematically showing a relation between a temperature characteristic of the MOS transistor and a temperature characteristic of an oscillation frequency of the ring oscillator.

FIG. 4 is a circuit diagram showing a configuration of an oscillator according to the first embodiment.

FIG. 5 is a diagram showing a flow of a current in the oscillator according to the first embodiment.

FIG. 6 depicts graphs each showing a result of simulation of a current in the oscillator according to the first embodiment.

FIG. 7 is a table indicating a result of the simulation of the oscillation frequency in the oscillator according to the first embodiment.

FIG. 8 is a circuit diagram showing a configuration of an oscillator according to a second embodiment.

FIG. 9 is a table indicating a relation between on/off of switches and values of a reference current.

FIG. 10 is a circuit diagram showing a configuration of an oscillator according to a third embodiment.

FIG. 11 depicts diagrams each showing an eye pattern of an output signal of each of the oscillators when noise is superimposed on the power supply voltage.

FIG. 12 is a circuit diagram showing a configuration of an oscillator according to a fourth embodiment.

### DETAILED DESCRIPTION

In the following, embodiments according to the present invention will be described with reference to the attached drawings. In each of the drawings, components having the same function are denoted by the same reference symbols, and the repetitive description thereof is omitted as needed.

As a premise for understanding an oscillator which will be described in the embodiments below, a relation between a metal oxide semiconductor (MOS) transistor constituting the oscillator and an oscillation frequency will be described.

A relation between a drain-source current I_{ds} and a gate-source voltage V_{gs} of the MOS transistor is, in general, expressed in the following expression with use of a threshold voltage Vₜ of the MOS transistor and a gain coefficient β.

$$\begin{matrix}[ Math . 1 ] & \\ {I}_{d s} = 0 \text{.5} β \cdot {( {V}_{g s} - {V}_{t} )}^{2} & [ 1 ]\end{matrix}$$

The gain coefficient β is expressed in the following expression with use of a mobility μ, a gate oxide film capacitor Cₒₓ, a channel width W and a channel length L of the MOS transistor.

$$\begin{matrix}[ Math . 2 ] & \\ β = μ {C}_{OX} \frac{W}{L} & [ 2 ]\end{matrix}$$

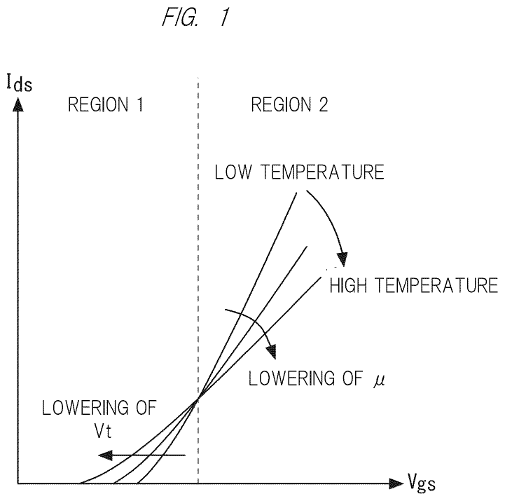

On the basis of the expression above, the relation between the drain-source current I_{ds} and the gate-source voltage V_{gs} will be described. FIG. 1 is a graph showing the relation between the drain-source current I_{ds} and the gate-source voltage V_{gs} of the MOS transistor. Since the gain coefficient β and the threshold voltage Vₜ of the MOS transistor each have a negative temperature characteristic, the relation between the drain-source current I_{ds} and the gate-source voltage V_{gs} changes according to temperature. Specifically, as the temperature rises, β in the expression [1] becomes smaller, and hence, a rate of change of the drain-source current I_{ds} becomes smaller. Accordingly, in FIG. 1, as the temperature rises, an inclination of the curve indicating the drain-source current I_{ds} becomes smaller. In addition, as the temperature rises, Vₜ in the expression [1] becomes smaller, so that the curve indicating the drain-source current I_{ds} shifts to the left side. Hence, as shown in FIG. 1, the relation between the drain-source current I_{ds} and the gate-source voltage V_{gs} is divided into two regions. The region 1 is a region in which the drain-source current I_{ds} becomes larger at high temperatures than at low temperatures. The region 2 is a region in which the drain-source current I_{ds} becomes larger at low temperatures than at the high temperatures.

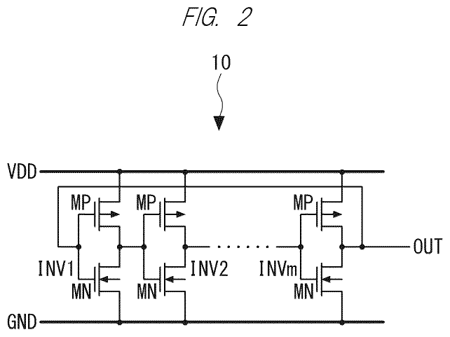

Next, a typical ring oscillator will be described. FIG. 2 is a circuit diagram showing a configuration of a typical ring oscillator 10. The ring oscillator 10 is configured such that complementary metal-oxide-semiconductor (CMOS) inverters INV1 to INVm in each of which a p-type transistor MP and an n-type transistor MN are connected in series are connected in parallel between a power supply VCC and the ground. Note that, however, m is an integer equal to or larger than 2. Note that, in the following description, the p-type transistor MP is also referred to as a tenth transistor, and the n-type transistor MN is also referred to as an eleventh transistor. In addition, in the following description, the power supply voltage output by the power supply VCC is denoted as a power supply voltage VCC.

An input of the CMOS inverter INV1 and an output of the CMOS inverter INVm are connected to an output terminal OUT. The outputs of the CMOS inverters INV1 to INVm−1 are connected to respective inputs of the CMOS inverter INV2 to the CMOS inverter INVm. In other words, when k is an integer equal to or lager than 1 and equal to or smaller than m−1, an output of the CMOS inverter INVk is connected to an input of the CMOS inverter INVk+1 adjacent thereto.

An oscillation frequency f_{OSC} of the ring oscillator 10 is expressed in the following expression, when rise and fall delay times of an output voltage per one inverter stage are each denoted as t_{d}.

$$\begin{matrix}[ Math . 3 ] & \\ {f}_{OSC} = \frac{1}{2 \cdot {t}_{d} \cdot m} & [ 3 ]\end{matrix}$$

In general, it is known that, as the drain-source current I_{ds} of the MOS transistor becomes larger, the delay time t_{d} per one inverter stage becomes smaller. Accordingly, due to the temperature characteristic of the MOS transistor, the temperature characteristic is generated also in the oscillation frequency f_{OSC} determined according to the delay time t_{d}.

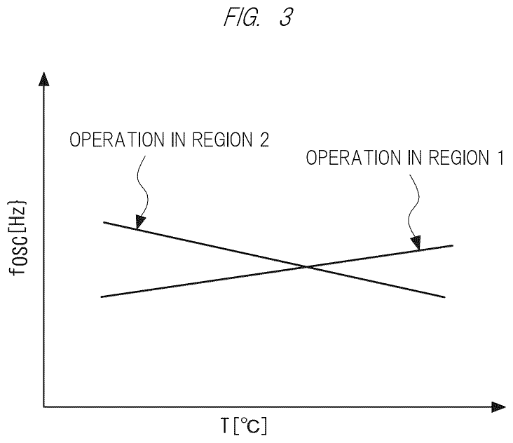

FIG. 3 is a graph schematically showing a relation between the temperature characteristic of the MOS transistor and the temperature characteristic of the oscillation frequency f_{OSC} of the ring oscillator 10. In the region 1 of FIG. 1, in a case in which the transistor included in the ring oscillator 10 is operated, the drain-source current I_{ds} becomes larger when the ambient temperature increases, and hence, according to the expression [3], the oscillation frequency f_{OSC} becomes larger. In this case, the oscillation frequency f_{OSC} has a positive temperature characteristic.

Conversely, in the region 2 of FIG. 1, in a case in which the transistor included in the ring oscillator 10 is operated, the drain-source current I_{ds} becomes smaller when the ambient temperature increases, and hence, according to the expression [3], the oscillation frequency f_{OSC} becomes smaller. In this case, the oscillation frequency f_{OSC} has a negative temperature characteristic.

In view of recent demand for achieving low power consumption, the ring oscillator is also required to reduce a power consumption P_{OSC}. In order to achieve this requirement, reduction in the power supply voltage VCC to be supplied to the ring oscillator and a current consumption I_{OSC} of the ring oscillator is considered to be effective. The power consumption P_{OSC} of the ring oscillator is expressed in the following expression.

$$\begin{matrix}[ Math . 4 ] & \\ {P}_{OSC} = {I}_{OSC} \cdot V DD & [ 4 ]\end{matrix}$$

The current consumption I_{OSC} of the ring oscillator is expressed by a sum of a gate charge/discharge current I_{charge} and a through current Iₚₑₙₑ of the MOS transistor.

$$\begin{matrix}[ Math . 5 ] & \\ {I}_{OSC} = {I}_{charge} + {I}_{pene} & [ 5 ]\end{matrix}$$

The gate charge/discharge current I_{charge} is expressed in the following expression. Note that, however, C is all gate capacitances of the MOS transistors constituting the ring oscillator 10.

$$\begin{matrix}[ Math . 6 ] & \\ {I}_{charge} = {f}_{OSC} \cdot C \cdot V DD & [ 6 ]\end{matrix}$$

The through current Iₚₑₙₑ is expressed in the following expression.

$$\begin{matrix}[ Math . 7 ] & \\ {I}_{p e n e} ∝ {f}_{OSC} \cdot {( V DD - {V}_{t} )}^{2} & [ 7 ]\end{matrix}$$

As described above, in order to reduce the power consumption P_{OSC} of the ring oscillator 10, it is effective to reduce the power supply voltage VCC.

In a case of simply referring to as a transistor below, it means a MOS transistor. As for the transistor, it is also abbreviated as Tr. One of the source and the drain of the MOS transistor is referred to as one end, the other thereof is also referred to as the other end, and the gate thereof is also referred to as a control terminal.

The oscillator according to Patent Document 1 described above prevents lowering of the oscillation frequency, in a situation in which the oscillation frequency lowers along with the temperature rise as seen in the region 2 described in FIG. 1. However, since an amount of variation of the oscillation frequency with the temperature rise is large, it is difficult to use the oscillator for the clock generation in the digital circuit, as described above.

### First Embodiment

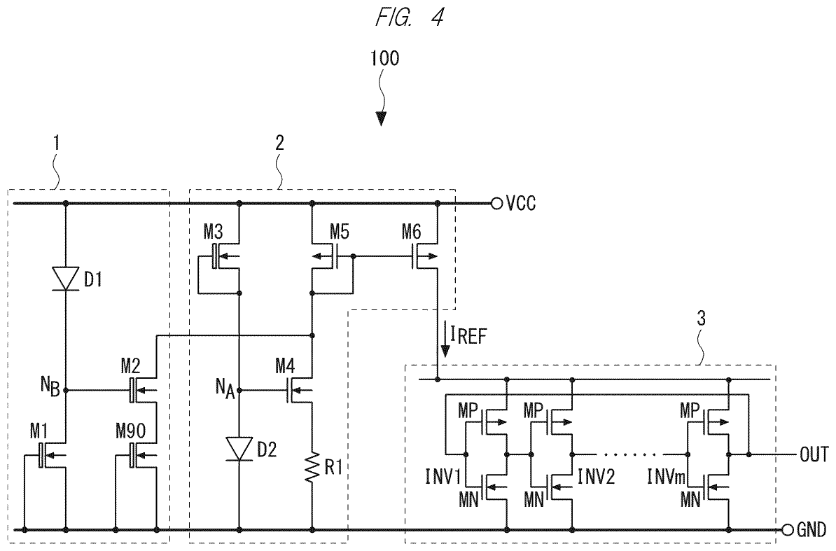

An oscillator 100 is a circuit which oscillates as a result of supply of a power supply voltage from a power supply. In the following description, the power supply voltage output by a power supply VCC is also referred to as the power supply voltage VCC. FIG. 4 is a circuit diagram showing an oscillator 100 according to the first embodiment. The oscillator 100 according to the first embodiment has a reference current source 1, a reference current source 2, and a ring oscillator 3. The reference current sources 1 and 2 are referred to as a first current source and a second current source, respectively.

In the oscillator 100, a current I_{REF} obtained by summing a current I₁ from the reference current source 1 having a positive temperature characteristic and a current I₂ from the reference current source 2 having a negative temperature characteristic is supplied to the ring oscillator 3. Accordingly, the oscillator 100 cancels out variation of the current I_{REF} due to variation in temperature, thereby suppressing the variation in temperature of the oscillation frequency of the ring oscillator 3.

The reference current source 1 is configured as a current source having the positive temperature characteristic. The reference current source 1 has a diode D1 and n-type transistors M1, M2, and M90. In the first embodiment, the n-type transistors M1, M2, and M90 are depletion-mode MOS transistors.

The diode D1 and the n-type transistor M1 are connected in series between the power supply VCC and a ground GND in this order. An anode of the diode D1 is connected to the power supply VCC. A cathode of the diode D1 is connected to a drain of the n-type transistor M1. A source and a gate of the n-type transistor M1 are connected to the ground GND.

The n-type transistors M2 and M90 are connected in series between the reference current source 2 and the ground GND in this order. A drain of the n-type transistor M2 is connected to a node between a drain of a p-type transistor M5 and a drain of an n-type transistor M4 of the reference current source 2, as described later. A source of the n-type transistor M2 is connected to a drain of the n-type transistor M90. A gate of the n-type transistor M2 is connected to a node NB between the cathode of the diode D1 and the drain of the n-type transistor M1. A source and a gate of the n-type transistor M90 are connected to the ground GND.

The n-type transistor M90 is provided as a resistor in the reference current source 2, and may be replaced with a typical resistor element. In the following description, the n-type transistor M9 is also referred to as a second resistor.

As described above, the reference current source 1 is configured using a depletion-mode MOS transistor, and accordingly functions as a normally-on type current source.

In the following description, the n-type transistors M1 and M2 are also referred to as first and second transistors, respectively. The n-type transistor M90 is also referred to as a twelfth transistor. The diode D1 is also referred to as a first diode.

The reference current source 2 is configured as current source having the negative temperature characteristic. The reference current source 2 has a diode D2, a resistor R1, n-type transistors M3 and M4, and p-type transistors M5 and M6. In the first embodiment, the n-type transistor M3 is a depletion-mode MOS transistor. The n-type transistor M4 and the p-type transistors M5 and M6 are enhancement-mode MOS transistors.

The n-type transistor M3 and the diode D2 are connected in series between the power supply VCC and the ground GND in this order. A drain of the n-type transistor M3 is connected to the power supply VCC. A source of the n-type transistor M3 is connected to a gate of the n-type transistor M3 and an anode of the diode D2. A cathode of the diode D2 is connected to the ground GND.

The p-type transistor M5, the n-type transistor M4, and the resistor R are connected in series between the power supply VCC and the ground GND in this order. A source of the p-type transistor M5 is connected to the power supply VCC. A drain of the p-type transistor M5 is connected to a gate of the p-type transistor M5, a drain of the n-type transistor M4, and a drain of the n-type transistor M2. The resistor R1 is connected between a source of the n-type transistor M4 and the ground GND. A gate of the n-type transistor M4 is connected to a node N_{A} between the source of the n-type transistor M3 and the anode of the diode D2.

The p-type transistors M5 and M6 constitute a current mirror circuit. A source of the p-type transistor M6 is connected to the power supply VCC. A drain of the p-type transistor M6 is connected to the ring oscillator 3. A gate of the p-type transistor M6 is connected to the gate of the p-type transistor M5.

As described above, the reference current source 2 is configured using a depletion-mode MOS transistor, and accordingly, functions as a normally-on type current source.

In the following description, the n-type transistors M3 and M4 are also referred to as third and fourth transistors, respectively. The p-type transistors M5 and M6 are also referred to as fifth and sixth transistors, respectively. The diode D2 is also referred to as a second diode, and the resistor R1 as a first resistor.

The ring oscillator 3 has the same configuration as that of the ring oscillator 10 in FIG. 2. The ring oscillator 3 is supplied with a current output from the drain of the p-type transistor M6 of the reference current source 2 as the reference current I_{REF}. The other configurations of the ring oscillator 3 are the same as those of the ring oscillator 10 in FIG. 2, and accordingly, the redundant description thereof will be omitted.

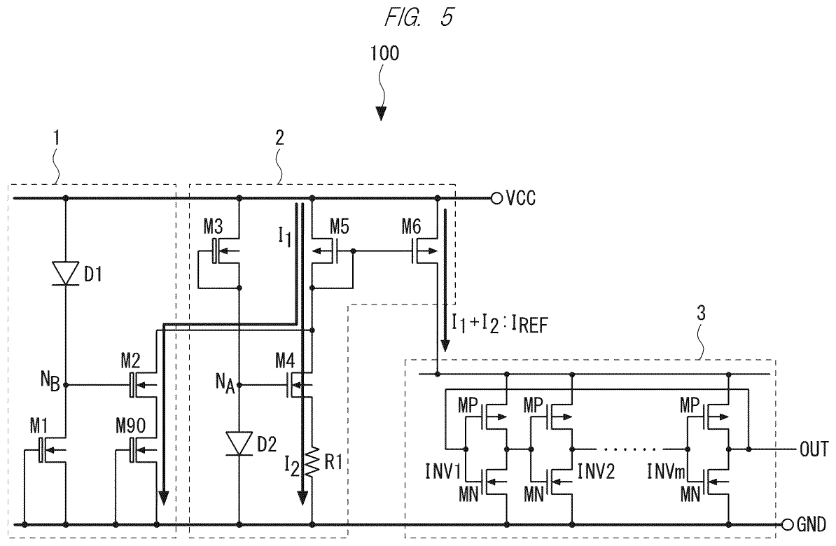

Next, an operation of the oscillator 100 will be described. First, the temperature characteristic of a current flowing in the reference current source 2 will be studied. FIG. 5 is a diagram showing a flow of a current in the oscillator 100 according to the first embodiment. A forward voltage of the diode D2 is set as V_{F}[D2], and the temperature as T. In a case in which the temperature characteristic of the forward voltage V_{F}[D2] of the diode D2 is negative, the following expression is satisfied.

$$\begin{matrix}[ Math . 8 ] & \\ \frac{{Δ V}_{F} [ D 2 ]}{Δ T} < 0 & [ 8 ]\end{matrix}$$

Hence, the temperature characteristic of a voltage V_{A} of the node N_{A} between the source of the n-type transistor M3 and the anode of the diode D2 is negative, as indicated in the following expression.

$$\begin{matrix}[ Math . 9 ] & \\ \frac{{Δ V}_{A}}{Δ T} < 0 & [ 9 ]\end{matrix}$$

Here, assuming that the temperature characteristic of the resistor R1 is approximately 0, the temperature characteristic of the current I₂ flowing through the n-type transistor M4 and the resistor R1 is also negative as indicated in the following expression. Note that the description that the temperature characteristic of the resistor R1 is approximately 0 means a case in which the temperature characteristic of the resistor R1 is equal to or close to 0. In order to supply the resistor R1 with the temperature characteristic having a value that is equal to or close to 0, for example, the resistor R1 may be configured as a polysilicon resistor.

$$\begin{matrix}[ Math . 10 ] & \\ \frac{Δ {I}_{2}}{Δ T} < 0 & [ 10 ]\end{matrix}$$

Next, the temperature characteristic of the current flowing in the reference current source 1 will be studied. The forward voltage of the diode D1 is set to V_{F}[D1]. In a case in which the temperature characteristic of the forward voltage V_{F}[D1] of the diode D1 is negative, the following expression is satisfied.

$$\begin{matrix}[ Math . 11 ] & \\ \frac{{Δ V}_{F} [ D 1 ]}{Δ T} < 0 & [ 11 ]\end{matrix}$$

Hence, the temperature characteristic of the voltage V_{B} at the node NB between the cathode of the diode D1 and the drain of the n-type transistor M1 is negative as indicated in the following expression.

$$\begin{matrix}[ Math . 12 ] & \\ \frac{{Δ V}_{B}}{Δ T} > 0 & [ 12 ]\end{matrix}$$

In a case in which the temperature characteristic between a drain-source voltage V_{DS}[M90] of the n-type transistor M90 is positive, the following expression is satisfied.

$$\begin{matrix}[ Math . 13 ] & \\ \frac{{Δ V}_{D S} [ M 90 ]}{Δ T} > 0 & [ 13 ]\end{matrix}$$

In this case, the temperature characteristic of the current I₁ flowing in the n-type transistors M2 and M90 is also positive as indicated in the following expression.

$$\begin{matrix}[ Math . 14 ] & \\ \frac{Δ {I}_{1}}{Δ T} > 0 & [ 14 ]\end{matrix}$$

In this manner described above, the current flowing in the p-type transistor M5 of the reference current source 2 is the sum of the current I₁ and the current I₂. Hence, the reference current I_{REF} flowing in the p-type transistor M6 which constitutes the current mirror circuit with the p-type transistor M5 is also the sum of the current I₁ and the current I₂.

$$\begin{matrix}[ Math . 15 ] & \\ {I}_{R B F} = {I}_{1} + {I}_{2} & [ 15 ]\end{matrix}$$

As indicated in the expression [15], the current I₁ and the current I₂ included in the reference current I_{REF} have mutually opposing temperature characteristics. Accordingly, it is found that variation of the current I₁ and variation of the current I₂ which are dependent on temperature cancel out each other. Hence, in the oscillator 100, it is possible to suppress the variation of the temperature of the reference current I_{REF}.

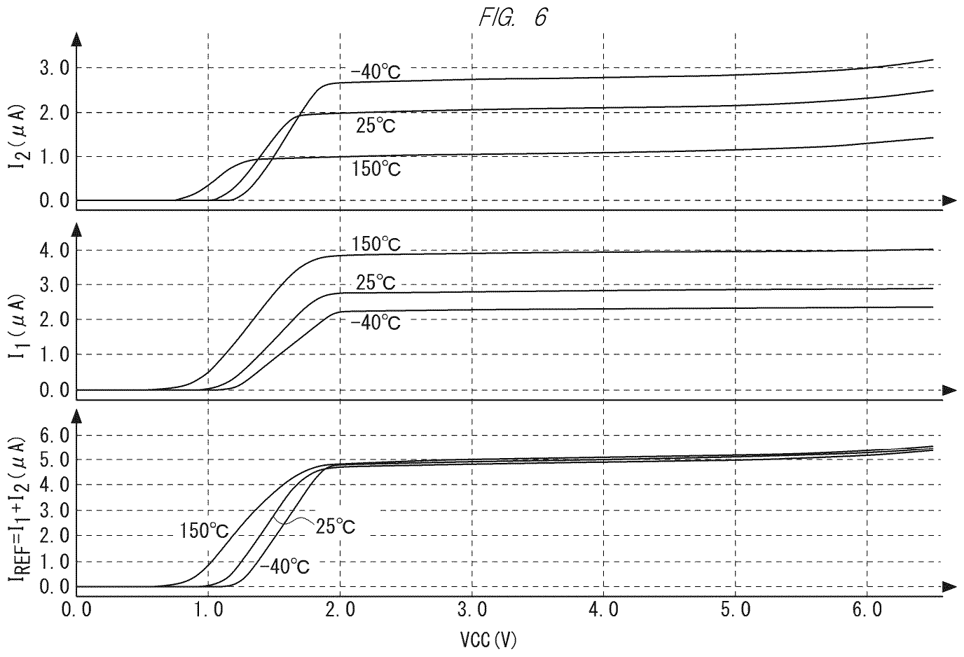

FIG. 6 depicts graphs each showing a result of simulation of the current in the oscillator 100 according to the first embodiment. As shown in FIG. 6, the current I₁ and the current I₂ have mutually opposing temperature characteristics. In contrast, the reference current I_{REF} that is the sum of the current I₁ and the current I₂ has a moderately positive temperature characteristic as a result of cancelling out the temperature characteristic of the current I₁ and the temperature characteristic of the current I₂. On the whole, in a case in which the power supply voltage VCC at which the transistor included in the oscillator 100 operates in the region 2 of FIG. 1 is equal to or larger than 1.9 V, the variation of the reference current I_{REF} can preferably be suppressed.

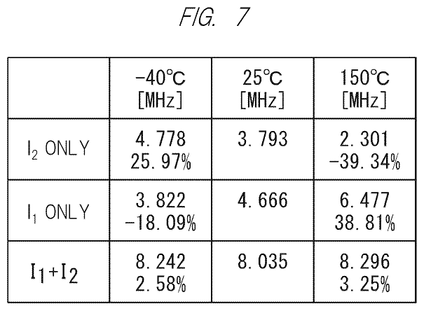

FIG. 7 is a table indicating a result of the simulation of the oscillation frequency in the oscillator 100 according to the first embodiment. As indicated in FIG. 7, it is found that, compared to a case in which the current I₁ or I₂ is supplied to the ring oscillator 3, supplying the current I_{REF} achieves further reduction in variation range of the oscillation frequency.

As described above, according to the present configuration, by summing the currents which are generated in the two reference current sources and have mutually opposite temperature characteristics and supplying the resultant summed current to the ring oscillator, the temperature variation of the current to be supplied to the ring the oscillator can be suppressed. As a result, the temperature variation of the oscillation frequency of the oscillator can be suppressed.

### Second Embodiment

In the first embodiment, the oscillator capable of reducing the temperature variation of the oscillation frequency has been described. However, according to variation in process or the like, an individual difference may occur in the oscillation frequency of the oscillator. In view of this, in the present embodiment, an oscillator which can adjust the oscillation frequency of the ring oscillator 3 by trimming the reference current I_{REF} will be described.

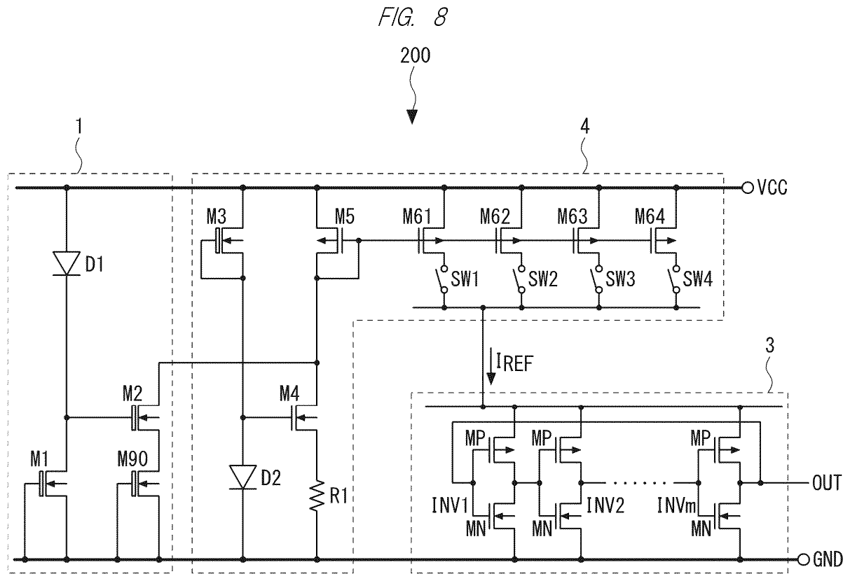

FIG. 8 is a circuit diagram showing a configuration of an oscillator according to the second embodiment. An oscillator 200 has a configuration in which the reference current source 2 of the oscillator 100 is replaced with a reference current source 4. The reference current source 4 has a configuration in which the p-type transistor M6 of the reference current source 2 is replaced with the p-type transistors M61 to M64. In addition, the reference current source 4 has the switches SW1 to SW4 added therein, compared to the reference current source 2.

Sources of the p-type transistors M61 to M64 are connected to the power supply VCC. The switches SW1 to SW4 are interposed between respective drains of the p-type transistors M61 to M64 and the ring oscillator 3. Gates of the p-type transistors M61 to M64 are connected to the gate of the p-type transistor M5.

In the present configuration, the p-type transistors M61 and M64 are transistors with different sizes from one another. By way of example, the p-type transistor M61 is a transistor that is the same size as the p-type transistor M5. The p-type transistor M62 is a transistor that is twice as large as the p-type transistor M5. The p-type transistor M63 is a transistor that is four times as large as the p-type transistor M5. The p-type transistor M64 is a transistor that is eight times as large as the p-type transistor M5.

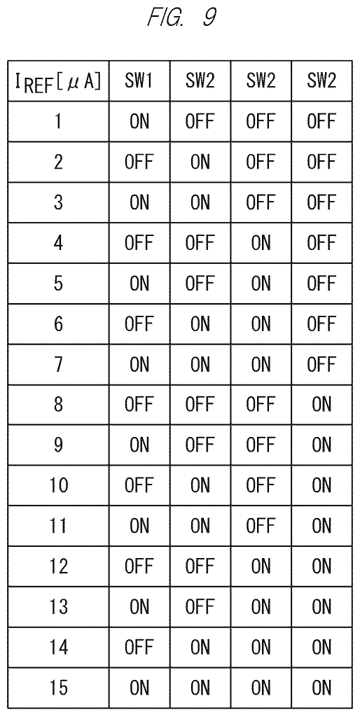

Accordingly, the oscillator 200 switches on/off of the switches SW1 to SW4, so that a value of the reference current I_{REF} can be adjusted. FIG. 9 is a table indicating a relation between on/off of the switches SW1 to SW4 and values of the reference current I_{REF}. In FIG. 9, an example in which a value obtained by summing the current I₁ and the current I₂ flowing in the p-type transistor M5 is 1 μA is indicated. As indicated in FIG. 9, any of the switches SW1 to SW4 which turn on are suitably selected, so that the values of the reference current I_{REF} can be adjusted in 15 stages.

A control section not shown may supply a switch signal to any of the switches SW1 to SW4 to achieve control of on/off of the switches SW1 to SW4.

Hence, the oscillator 200 can suppress variation of the oscillation frequency of the ring oscillator 3 attributable to variation in process by trimming of the reference current I_{REF}.

### Third Embodiment

In the oscillator according to the embodiments described above, when noise is superimposed on the power supply voltage VCC, the noise propagates into the ring oscillator 3. As a result, jitter may appear on an output signal OUT to be used as a clock signal.

For example, a case in which the oscillator according to the embodiments described above is mounted in an integrated circuit (IC) provided in an automobile will be studied. As for noise immunity to the IC for the automobile, for example, there are International Electrotechnical Commission (IEC) standards that are attracting attention in the automotive industry. In the IEC standards, as immunity testing for electromagnetic compatibility (EMC), IEC 62132-4 (direct power injection (DPI) method) is standardized. In the DPI method, a radio frequency (RF) signal in a range of normally 150 KHz to 1 GHz is injected into the local pins (pins which are connected to components including other ICs in an electronic control unit (ECU) and are not connected to external components outside the ECU), causing a noise of ±600 mV (on a 50-22 basis) to be superimposed on power supply terminals. As a result, even in such a situation that the noise is superimposed on the power supply terminals in the IC, the IC is required to have no malfunctions.

When the noise is superimposed on the power supply voltage, the noise may be superimposed on an output signal of the oscillator mounted in the IC. Hence, an oscillator having an excellent noise immunity is demanded. In view of this, in the present embodiment, an oscillator capable of suppressing an effect caused by the noise superimposed on the power supply voltage VCC will be described.

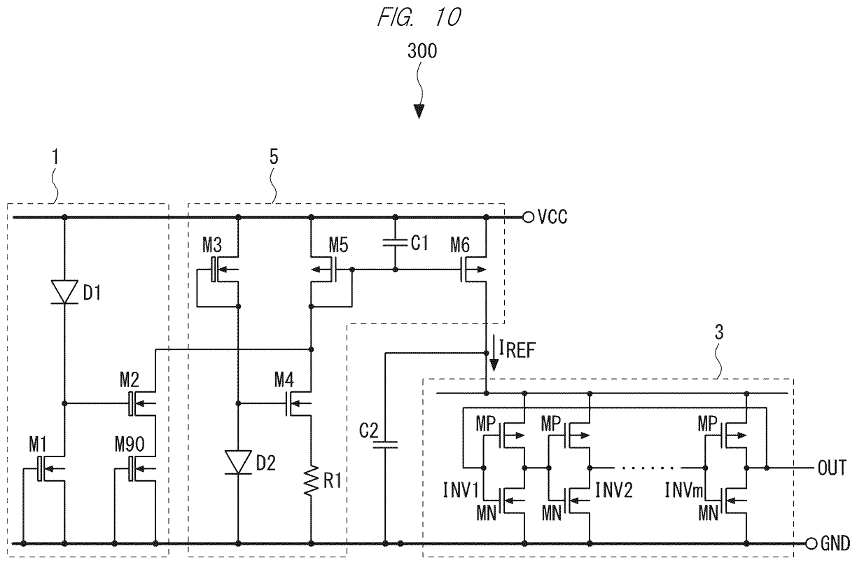

FIG. 10 is a circuit diagram showing a configuration of an oscillator 300 according to the third embodiment. The oscillator 300 has a configuration in which the reference current source 2 of the oscillator 100 according to the first embodiment is replaced with a reference current source 5. In addition, the oscillator 300 has a capacitor C2 added therein, compared to the oscillator 100.

The reference current source 5 has a configuration in which a capacitor C1 is added in the reference current source 2. The capacitor C1 is connected to the power supply VCC and a node between the gate of the p-type transistor M5 and the gate of the p-type transistor M6. A route for introducing noise superimposed on the power supply voltage through the capacitor C1 is also referred to as a first bypass route. In addition, the capacitor C1 is also referred to as a first capacitor.

The capacitor C2 is connected between the drain of the p-type transistor M6 and the ground GND. A route for introducing noise superimposed on the power supply voltage through the capacitor C2 is also referred to as a second bypass route. In the following description, the capacitor C2 is also referred to as a second capacitor.

Next, noise reduction owing to the capacitor C1 and C2 will be described. In the reference current source 5, providing the capacitor C1 makes it possible to reduce the effect of the noise being superimposed on the p-type transistor M5. At this time, the capacitor C1 may be designed such that an impedance of the capacitor C1 is smaller than an impedance of the p-type transistor M5.

Here, a transconductance of the p-type transistor M5 is denoted as gm[M5]. A frequency of a noise to be applied to the power supply VCC is denoted as f. At this time, in order to make the impedance of the capacitor C1 smaller than the impedance of the p-type transistor M5, the following expression is satisfied.

$$\begin{matrix}[ Math . 16 ] & \\ \frac{1}{g m [ M 5 ]} > \frac{1}{2 π f C 1} & [ 16 ]\end{matrix}$$

Accordingly, the capacitor C1 is expressed in the following expression.

$$\begin{matrix}[ Math . 17 ] & \\ C 1 > \frac{g m [ M 5 ]}{2 π f} & [ 17 ]\end{matrix}$$

In addition, providing the capacitor C2 in the oscillator 300 makes it possible to reduce the effect on the ring oscillator 3 caused by the noise being superimposed on the p-type transistor M6. At this time, as indicated in the following expression, the capacitor C2 may be designed such that the impedance of the capacitor C2 to the noise becomes smaller than the impedance of the p-type transistor M6. Here, variation in voltage between the drain and the source of the p-type transistor M6 when the noise of the frequency f is applied to the p-type transistor M6 is denoted as ΔV_{DS}[M6]. In addition, variation in current between the drain and the source of the p-type transistor M6 is denoted as ΔI_{DS}[M6].

$$\begin{matrix}[ Math . 18 ] & \\ \frac{{Δ V}_{D S} [ M 6 ]}{Δ {I}_{D S} [ M 6 ]} > \frac{1}{2 π f C 2} & [ 18 ]\end{matrix}$$

Accordingly, the capacitor C2 is expressed in the following expression.

$$\begin{matrix}[ Math . 19 ] & \\ C 2 > \frac{Δ {I}_{D S} [ M 6 ]}{{Δ V}_{D S} [ M 6 ]} \cdot \frac{1}{2 π f} & [ 19 ]\end{matrix}$$

As described above, the capacitors C1 and C2 are designed in such a manner as to satisfy the expressions [17] and [19], so that the effect on the ring oscillator 3 caused by the noise being superimposed on the power supply voltage VCC can effectively be reduced.

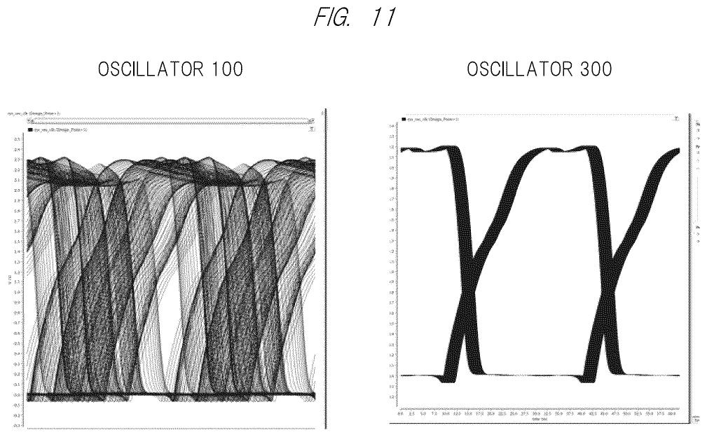

FIG. 11 depicts diagrams each showing an eye pattern of an output signal of each of the oscillators when noise is superimposed on the power supply voltage VCC. In FIG. 11, a noise of ±600 m V is superimposed on the power supply voltage VCC. Under this condition, the eye pattern in the oscillator 100 and the eye pattern of the oscillator 300 are compared with each other. In the eye pattern in the oscillator 100, the output signal OUT is spreading, and the eye is considerably narrowing. In contrast, in the eye pattern of the oscillator 300, spreading of the output signal OUT is remarkably suppressed, and the eye can be clearly recognized. Hence, in the oscillator 300, providing the bypass routes for the noise makes it possible to effectively suppress lowering of the quality of the output signal due to the noise.

As described above, according to the oscillator 300, providing the bypass routes for the power supply noise propagating into the ring oscillator 3 makes it possible to suppress the effect of the noise on the ring oscillator 3.

### Fourth Embodiment

In the embodiments described above, the oscillator in which the n-type transistors M1 to M3 and M90 are depletion-mode MOS transistors has been described. However, some of the n-type transistors M1 to M3 and M90 can be replaced with enhancement-mode MOS transistors.

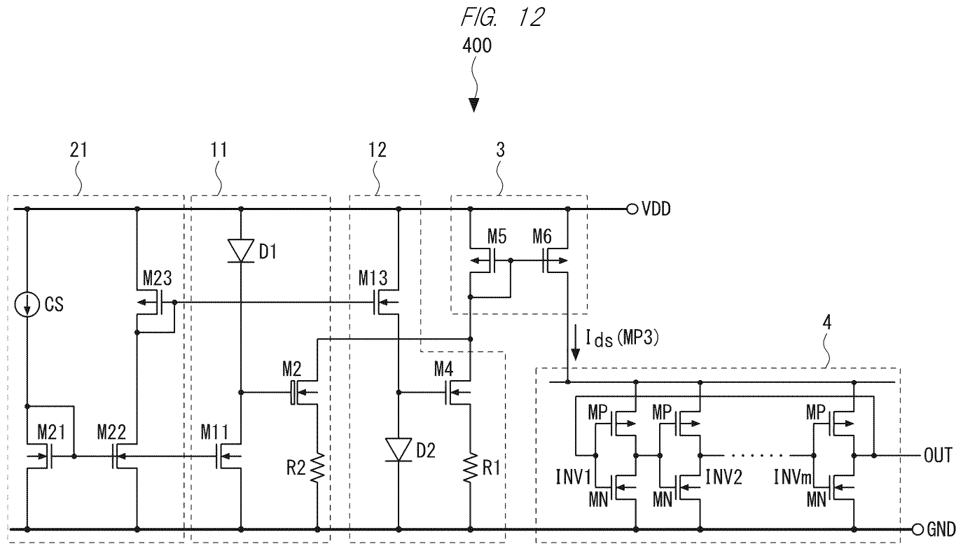

FIG. 12 is a circuit diagram showing a configuration of an oscillator 400 according to the fourth embodiment. The oscillator 400 has a configuration that the reference current sources 1 and 2 of the oscillator 100 are replaced with reference current sources 11 and 12, respectively. In addition, the oscillator 400 has a bias circuit 21 added thereto, compared to the oscillator 100.

The reference current source 11 has a configuration that the depletion-mode n-type transistor M1 of the reference current source 1 is replaced with an enhancement-mode n-type transistor M11. The reference current source 12 has a configuration that the depletion-mode n-type transistor M3 of the reference current source 2 is replaced with a resistor R2.

The bias circuit 21 has enhancement-mode n-type transistors M21 and M22, a p-type transistor M23, and a current source CS. The n-type transistors M21 and M22, and the p-type transistor M23 are enhancement-mode MOS transistors. In the following description, the n-type transistors M21 and M22, and the p-type transistor M23 are also referred to as seventh to ninth transistors, respectively.

The current source CS and the n-type transistor M21 are connected in series between the power supply VCC and the ground GND in this order. The current source CS is connected between the power supply VCC and a drain of the n-type transistor M21. A source of the n-type transistor M21 is connected to the ground GND. A gate of the n-type transistor M21 is connected to a drain of the n-type transistor M21, a gate of the n-type transistor M22, and a gate of the n-type transistor M11.

The p-type transistor M23 and the n-type transistor M22 are connected in series between the power supply VCC and the ground GND in this order. A source of the p-type transistor M23 is connected to the power supply VCC. A drain of the p-type transistor M23 is connected to a gate of the p-type transistor M23, a gate of the n-type transistor M13, and a drain of the n-type transistor M22. A source of the n-type transistor M22 is connected to the ground GND. The gate of the n-type transistor M22 is connected to the gate of the n-type transistor M21 and the gate of the n-type transistor M11, as described above.

Accordingly, the n-type transistors M11, M21, and M22 constitute a current mirror circuit. The n-type transistors M13 and M23 constitute a current mirror circuit. Hence, a bias voltage generated by the bias circuit 21 is applied to the gates of the n-type transistors M11 and M13.

According to the present configuration, the oscillator 400 can perform the same operation as that of the oscillator 100 according to the first embodiment. Hence, even if some of the depletion-mode transistors included in the oscillator are replaced with enhancement-mode transistors, it is found that the oscillator capable of performing the same operation can be obtained.

### Other Embodiments

Although the present disclosure has been described above with reference to the embodiments, the present disclosure is not limited to the above-described embodiments. Various modifications that can be understood by those skilled in the art can be made to the configurations and details of the present disclosure within the scope and spirit of the disclosure. Further, the embodiments may be combined with one another as appropriate.

In the embodiments described above, a description has been made, assuming that the reference current source 1 and the reference current source 11 each have the n-type transistor M90 provided therein, but the n-type transistor M90 may be replaced with a resistor. At this time, in order to suppress the temperature characteristic, the resistor may preferably be configured as a polysilicon resistor.

Each of the drawings is merely an example to illustrate one or more embodiments. Each of the drawing is not associated with only one specific embodiment, but may be associated with one or more other embodiments. As will be understood by those skilled in the art, various features or steps described with reference to any one of the drawings may be combined with features or steps shown in one or more other drawings in order to create, for example, an embodiment that is not explicitly shown in the drawings or described in the specification. Not all of the features or steps shown in any one of the drawings to describe an example embodiment are necessarily indispensable, and some features or steps may be omitted. The order of steps in any of the drawings may be changed as appropriate.

What is claimed is:

1. An oscillator comprising:
a first current source which generates a first current having a positive temperature characteristic according to a power supply voltage output from a power supply;
a second current source which generates a second current having a negative temperature characteristic according to the power supply voltage, and outputs a reference current obtained by summing the first current and the second current; and
a ring oscillator which outputs an output signal with an oscillation frequency according to the reference current, and includes a plurality of inverters in which transistors of a first conductivity type and transistors of a second conductivity type are complementarily connected,
wherein the first current source includes
a first diode and a first transistor of the first conductivity type which are connected in series between the power supply and a ground in this order, and
a second transistor of the first conductivity type and a second resistor which are connected in series between the second current source and the ground in this order,
wherein a control terminal of the second transistor is connected to a node between the first diode and the first transistor,
wherein a control terminal of the first transistor is connected to the ground,
wherein the second current source includes
a third transistor of the first conductivity type and a second diode which are connected in series between the power supply and the ground in this order,
a fifth transistor of the second conductivity type, a fourth transistor of the second conductivity type, and a first resistor which are connected in series between the power supply and the ground in this order, and
a sixth transistor of the second conductivity type having one end connected between the power supply and the ring oscillator, and constituting a current mirror with the fifth transistor,
wherein a control terminal of each of the third and fourth transistors is connected to an anode of the second diode, and
wherein the second transistor is connected between a node between the fourth transistor and the fifth transistor and the second resistor.

2. The oscillator according to claim 1,
wherein the first to the third transistors are depletion-mode metal oxide semiconductor (MOS) transistors, and
wherein the fourth to the sixth transistors are enhancement-mode MOS transistors.

3. The oscillator according to claim 1, further comprising:
a bias circuit which supplies the first current source with a bias voltage,
wherein the bias circuit includes
a current source and a seventh transistor of the first conductivity type which are connected in series between the power supply and the ground in this order, and
a ninth transistor of the first conductivity type and an eighth transistor of the second conductivity type which are connected in series between the power supply and the ground in this order,
wherein the first, the seventh, and the eighth transistors constitute a current mirror,
wherein the third and the ninth transistors constitute a current mirror,
wherein the first and the third to the ninth transistors are enhancement-mode metal oxide semiconductor (MOS) transistor, and
wherein the second transistor is a depletion-mode MOS transistor.

4. The oscillator according to claim 2,
wherein the MOS transistor has a drain-source current having a negative temperature characteristic, in a case in which a gate-source voltage is larger than a predetermined value, and
wherein the power supply voltage is set to such a value that gate-source voltages of the first to the sixth transistors and the transistors of the ring oscillator are larger than the predetermined value.

5. The oscillator according to claim 1,
wherein the sixth transistor includes
a plurality of transistors which are connected in parallel and have with different sizes from one another, and
a plurality of switches each being inserted between each of the plurality of transistors and the ring oscillator, and
wherein a value of the reference current is switchable by switching each of the plurality of switches.

6. The oscillator according to claim 1,
wherein the second current source includes a first bypass route connecting the power supply and control terminals of the fifth and the sixth transistors, and
wherein the first bypass route is configured such that an impedance to noise superimposed on the power supply voltage supplied to the fifth transistor is lower than the fifth transistor.

7. The oscillator according to claim 6, wherein the second current source further includes a first capacitor connected between the power supply and a node between the control terminals of the fifth and the sixth transistors.

8. The oscillator according to claim 1, comprising:
a second bypass route connecting the second current source and the ground without the ring oscillator being interposed therein,
wherein the second bypass route is configured such that an impedance to noise superimposed on the reference current supplied to the ring oscillator is lower than the ring oscillator.

9. The oscillator according to claim 1, further comprising:
a second capacitor connected between a node between the second current source and the ring oscillator and the ground.

10. The oscillator according to claim 1, wherein the first resistor is configured such that a temperature characteristic of a resistance value is a value equal to or close to 0.

11. The oscillator according to claim 10, wherein the first resistor is configured as a polysilicon resistor.

12. The oscillator according to claim 1,
wherein each of the plurality of inverters of the ring oscillator includes a tenth transistor of the first conductivity type, one end of which being supplied with the reference current, and an eleventh transistor of the second conductivity type, one end of which being connected to the tenth transistor and the other end of which being connected to the ground, gates of the tenth and the eleventh transistors are connected with each other as an input of the inverter, and a node between the tenth transistor and the eleventh transistor is set as an output, and
wherein an input of the inverter in the first stage and an output of the inverter in the final stage are connected, and in the inverter in the second stage to the inverter in the stage immediately preceding the final stage, the output of the inverter in the preceding stage is connected to the input of the inverter in the succeeding stage.

13. The oscillator according to claim 1, wherein the second resistor is a twelfth transistor of the first conductivity type which is connected between the second transistor and the ground, and which has a control terminal being connected to the ground.

14. The oscillator according to claim 1, wherein the first conductive type is an n type, and the second conductive type is a p type.
